(19) United States
(12) Patent Application Publication
(10) Pub. No.: US 2017/0092561 A1
(43) Pub. Date: Mar. 30, 2017

(54) THERMAL MANAGEMENT SOLUTIONS FOR MICROELECTRONIC DEVICES USING JUMPING DROPS VAPOR CHAMBERS

(71) Applicant: INTEL CORPORATION, Santa Clara, CA (US)

(72) Inventors: Feras Eid, Chandler, AZ (US); Arnab Choudhury, Chandler, AZ (US)

(73) Assignee: INTEL CORPORATION, Santa Clara, CA (US)

(21) Appl. No.: 14/863,580

(22) Filed: Sep. 24, 2015

(51) Int. Cl. H01L 23/427; H01L 25/065; H01L 21/48; H01L 23/373

(52) U.S. Cl. CPC H01L 23/427; H01L 23/373; H01L 25/0652; H01L 21/4882

(57) ABSTRACT

A thermal management solution may be provided for a microelectronic system, wherein a jumping drops vapor chamber is utilized between at least one microelectronic device and an integrated heat spreader. The microelectronic system may comprise a microelectronic device attached by an active surface thereof to a microelectronic substrate. The integrated heat spreader, having a first surface and an opposing second surface, is also attached to the microelectronic substrate with a jumping drops vapor chamber disposed between a back surface of the microelectronic device and the integrated heat spreader second surface. The jumping drops vapor chamber may comprise a vapor space defined by a hydrophilic evaporation surface on the microelectronic device back surface, a hydrophobic condensation surface on the integrated heat spreader second surface, and at least one sidewall extending between the hydrophilic evaporation surface and the hydrophobic condensation surface with a working fluid disposed within the vapor space.

### TECHNICAL FIELD

Embodiments of the present description generally relate to the removal of heat from microelectronic devices, and, more particularly, to thermal management solutions wherein a jumping drops vapor chamber is utilized between a microelectronic device and an integrated heat spreader.

### BACKGROUND

Higher performance, lower cost, increased miniaturization of integrated circuit components, and greater packaging density of integrated circuits are ongoing goals of the microelectronic industry. As these goals are achieved, microelectronic devices become smaller. Accordingly, the density of power consumption of the integrated circuit components in the microelectronic devices has increased, which, in turn, increases the average junction temperature of the microelectronic device. If the temperature of the microelectronic device becomes too high, the integrated circuits of the microelectronic device may be damaged or destroyed. This issue becomes even more critical when multiple microelectronic devices are incorporated in close proximity to one another in a multiple microelectronic device package, also known as a multi-chip package. Thus, thermal transfer solutions, such as integrated heat spreaders, must be utilized to remove heat from the microelectronic devices. However, the difficulty and cost of fabricating current designs for integrated heat spreaders for multi-chip packages has become an issue for the microelectronic industry.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIGS. 1-3 are side cross-sectional views of microelectronic systems, as known in the art.

FIG. 4 is a side cross-sectional view of a microelectronic system including jumping drops vapor chambers disposed between back surfaces of microelectronic devices and an integrated heat spreader, according to an embodiment of the present description.

FIG. 5 is an enlargement of area 5 of FIG. 4 illustrating a side cross-sectional view of a jumping drops vapor chamber, according to an embodiment of the present description.

FIG. 6 is a flow chart of a process for fabricating a microelectronic system including a jumping drops vapor chamber disposed between a back surface of a microelectronic device and an integrated heat spreader, according to the present description.

FIG. 7 is an electronic device/system, according to an embodiment of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

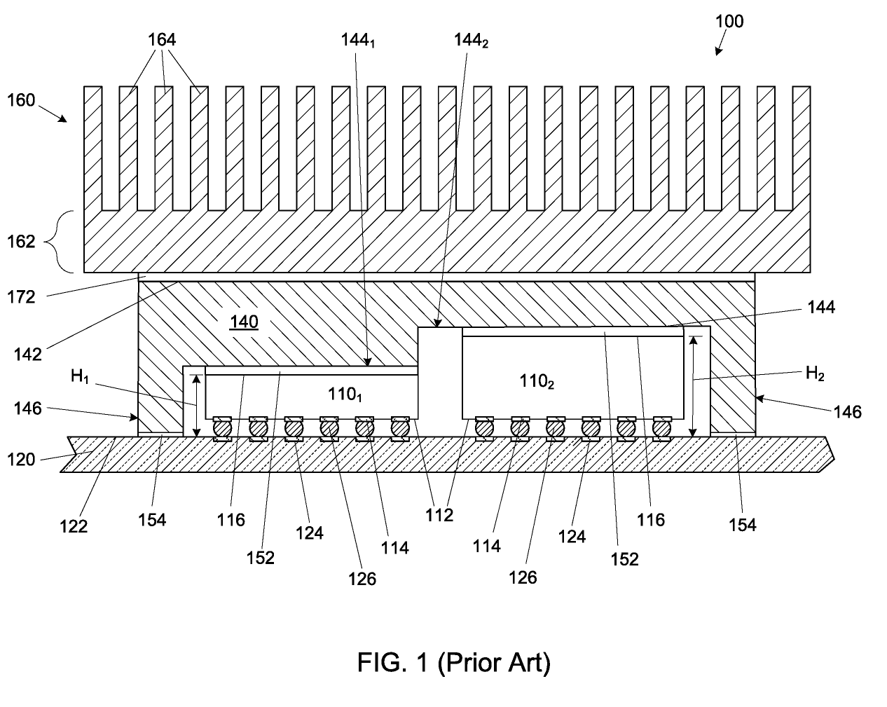

FIGS. 1-3 illustrate microelectronic systems having multiple microelectronic devices coupled with known integrated heat spreaders. In the production of microelectronic systems, microelectronic devices are generally mounted on microelectronic substrates, which provide electrical communication routes between the microelectronic devices and with external components. As shown in FIG. 1, a microelectronic system 100 may comprise a plurality of microelectronic devices (illustrated as elements 110₁ and 110₂), such as microprocessors, chipsets, graphics devices, wireless devices, memory devices, application specific integrated circuits, combinations thereof, stacks thereof, or the like, attached to a first surface 122 of a microelectronic substrate 120, such as a printed circuit board, a motherboard, and the like, through a plurality of interconnects 126, such as reflowable solder bumps or balls, in a configuration generally known as a flip-chip or controlled collapse chip connection (“C4”) configuration. The device-to-substrate interconnects 126 may extend from bond pads 114 on an active surface 112 of each of the microelectronic devices 110₁ and 110₂ and bond pads 124 on the microelectronic substrate first surface 122. The microelectronic device bond pads 114 of each of the microelectronic devices 110₁ and 110₂ may be in electrical communication with integrated circuitry (not shown) within the microelectronic devices 110₁ and 110₂. The microelectronic substrate 120 may include at least one conductive route (not shown) extending therethrough from at least one microelectronic substrate bond pad 124 to external components (not shown) and/or between at least two microelectronic substrate bond pads 124.

The microelectronic substrate 120 may be primarily composed of any appropriate material, including, but not limited to, bismaleimine triazine resin, fire retardant grade 4 material, polyimide materials, glass reinforced epoxy matrix material, and the like, as well as laminates or multiple layers thereof. The microelectronic substrate conductive routes (not shown) may be composed of any conductive material, including but not limited to metals, such as copper and aluminum, and alloys thereof. As will be understood to those skilled in the art, microelectronic interposer conductive routes (not shown) and the microelectronic substrate conductive routes (not shown) may be formed as a plurality of conductive traces (not shown) formed on layers of dielectric material (constituting the layers of the microelectronic substrate material), which are connected by conductive vias (not shown).

The device-to-substrate interconnects 126 can be made of any appropriate material, including, but not limited to, solders materials. The solder materials may be any appropriate material, including but not limited to, lead/tin alloys, such as 63% tin/37% lead solder, and high tin content alloys (e.g. 90% or more tin), such as tin/bismuth, eutectic tin/silver, ternary tin/silver/copper, eutectic tin/copper, and similar alloys. When the microelectronic devices 110₁ an 110₂ are attached to the microelectronic substrate 120 with device-to-substrate interconnects 126 made of solder, the solder is reflowed, either by heat, pressure, and/or sonic energy to secure the solder between the microelectronic device bond pads 114 and the microelectronic substrate bond pads 124.

As further illustrated in FIG. 1, an integrated heat spreader 140 may be in thermal contact with the microelectronic devices 110₁ and 110₂. The integrated heat spreader 140 may be made of any appropriate thermally conductive material, such a metals and alloys, including, but not limited to, copper, aluminum, and the like.

The integrated heat spreader 140 may have a first surface 142 and an opposing second surface 144, wherein the integrated heat spreader second surface 144 includes at least two levels (illustrated as elements 144₁ and 144₂). As illustrated, the differing integrated heat spreader second surface levels 144₁, and 144₂ may compensate for differing heights H₁ and H₂ of the microelectronic devices 110₁ and 110₂ (i.e. the distance between the microelectronic substrate first surface 122 and a back surface 116 of each microelectronic devices 110₁ and 110₂), respectively, in order to make thermal contact therebetween. A thermal interface material 152, such as a thermally conductive grease or polymer, may be disposed between each integrated heat spreader second surface levels 144₁ and 144₂ and its respective back surface 116 of each microelectronic device 110₁ and 110₂ to facilitate heat transfer therebetween and to compensate for tolerances.

The integrated heat spreader 140 may include at least one footing 146 extending between the integrated heat spreader second surface 144 and the microelectronic substrate 120, wherein the integrated heat spreader footing 146 may be attached to the microelectronic substrate first surface 122 with an adhesive material 154.

As still further illustrated in FIG. 1, the integrated heat spreader 140 may be in contact with high surface area heat dissipation structure 160, which may comprise a conductive base plate 162 having a plurality of fins or projections 164 extending from the conductive base plate 162, wherein the high surface area heat dissipation structure 160 assists in dissipating heat from the integrated heat spreader 140, as will be understood to those skilled in the art. A thermal interface material 172, such as a thermally conductive grease or polymer, may be disposed between the integrated heat spreader first surface 142 and the high surface area heat dissipation structure 160 to facilitate heat transfer therebetween.

As will be understood to those skilled in the art, the fabrication of the integrated heat spreader 140 shown in FIG. 1 may require expensive stamping equipment able to achieve high tonnage stamping forces in order to form complex elements, such as the differing integrated heat spreader levels 144₁ and 144₂.

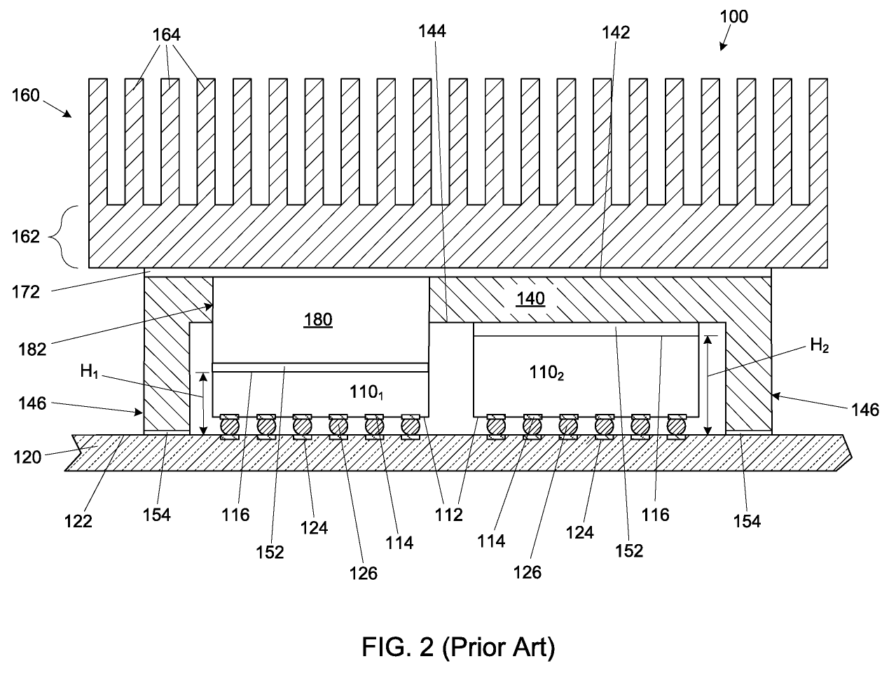

FIG. 2 illustrates another known integrated heat spreader 140 which does not require the formation of differing integrated heat spreader levels 144₁ and 144₂, as illustrated in FIG. 1. As illustrated, the differing heights H₁ and H₂ of the microelectronic devices 110₁ and 110₂ (i.e. the distance between the microelectronic substrate first surface 122 and the back surface 116 of each microelectronic devices 110₁ and 110₂) is compensated for by forming an opening 182 from the integrated heat spreader first surface 142 to the integrated heat spreader second surface 144, and inserting a heat slug 180 into the opening 182 to thermally contact the back surface 116 of the microelectronic device 110₁. As will be understood to those skilled in the art, the fabrication of the integrated heat spreader 140 shown in FIG. 2 may require expensive processing steps for its formation.

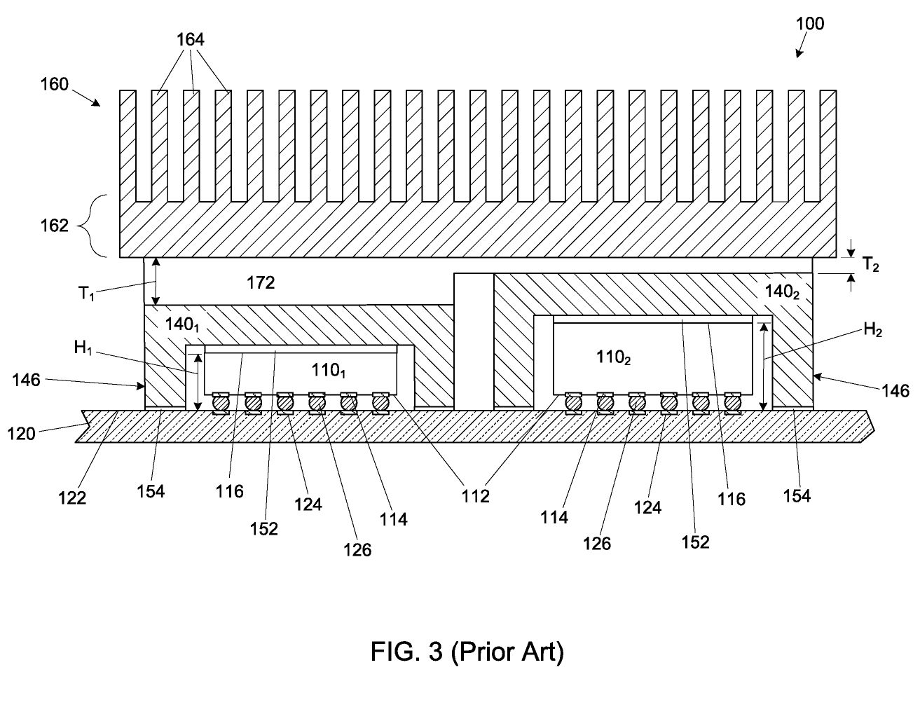

FIG. 3 illustrates still another known microelectronic system 100 which does not require the formation of differing integrated heat spreader levels 144₁ and 144₂, as illustrated in FIG. 1, or the insertion of the heat slug 180, as shown in FIG. 2. As shown in FIG. 3, individual integrated heater spreaders 140₁ and 140₂ can be fabricated for each of the microelectronic device 110₁ and 110₂, respectively, and the high surface area heat dissipation structure 160 may be in thermal contact with each of the integrated heat spreaders 140₁ and 140₂ through the thermal interface material 172, wherein differing heights H₁ and H₂ of the microelectronic devices 110₁ and 110₂ are compensated for by varying the thickness (see elements T₁ and T₂) of the thermal interface material 172. As will be understood to those skilled in the art, the use of high thickness T₁ areas for the thermal interface material 172 may be detrimental to heat transfer, and the microelectronic devices 110₁ and 110₂ may be in close proximity to one another due to bandwidth requirements, such that individual integrated heat spreaders 140₁ and 140₂ would not be feasible.

Embodiments of the present description relate to thermal solutions for microelectronic systems comprising a jumping drops vapor chamber disposed between an integrated heat spreader and a back surface of the microelectronic device in lieu of a thermal interface material.

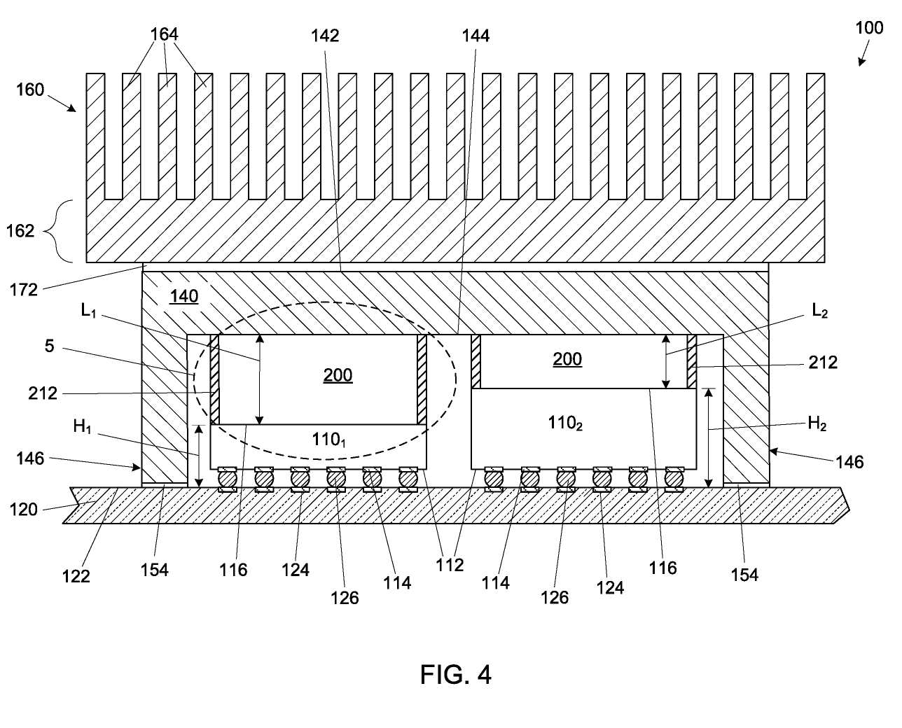

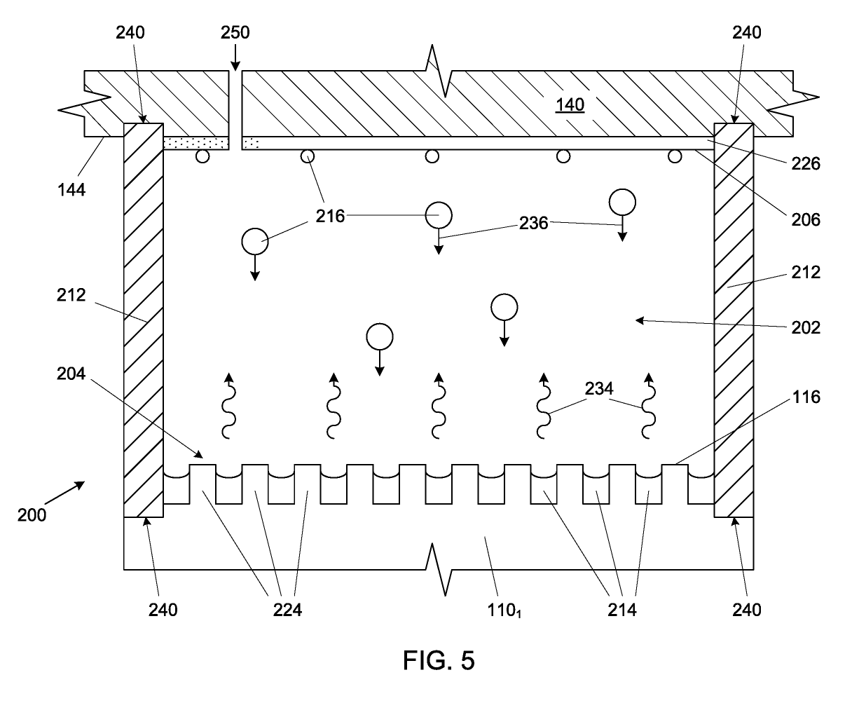

As illustrated in FIGS. 4 and 5, a jumping drops vapor chamber 200 may be placed between the back surface 116 of at least one microelectronic device 110₁ and 110₂ and the integrated heat spreader 140. As will be understood to those skilled in the art and as shown in FIG. 5, the jumping drops vapor chamber 200 may comprise a vapor space 202, which may be sealed, defined by a hydrophilic evaporation surface 204 formed on the microelectronic device back surface 116, an opposing hydrophobic condensation surface 206 formed on the integrated heat spreader second surface 144, and at least one sidewall 212 extending between the hydrophilic evaporation surface 204 and the hydrophobic condensation surface 206, wherein a working fluid 214 is disposed within the vapor space 202. The working fluid 214 may be any appropriate material, including, but not limited to, deionized water and dielectric liquids. It is understood that the amount of working fluid 214 within the vapor space 202 is dependent on the liquid used, the size of the vapor space 202, and various operating parameters.

As illustrated in FIG. 5, in one embodiment of the present description, the hydrophilic evaporation surface 204 may include projections or wicks 224 to render the back surface 116 of the microelectronic device 110₁ hydrophilic. The projections or wicks 224 may be formed by machining the back surface 116 of the microelectronic devices 110₁ and 110₂, including but not limited to skiving, dicing, and laser ablation. In an embodiment of the present description, the hydrophobic condensation surface 206 may be formed by coating the integrated heat spreader second surface 144 with a hydrophobic layer 226, such as a self-assembled monolayer material, including but not limited to thiols or silanes. As such self-assembled monolayers are only a few nanometers thick, they may have a negligible impact on thermal conductivity. In a specific embodiment, the hydrophobic layer 226 may be formed by depositing silver nanoparticles on the integrated heat spreader second surface 144 by electroless galvanic deposition followed by a monolayer coating of 1-hexadecanethiol.

In operation, as shown in FIG. 5, the working fluid 214 evaporates at hydrophilic evaporation surface 204 when the microelectronic device 110₁ heats up. The evaporated working fluid 214 flows to the hydrophobic condensation surface 206 (shown by waving lines 234). At the hydrophobic condensation surface 206, which is cooler than hydrophilic evaporation surface 204, the working fluid 214 condenses, which transports the heat away from the microelectronic device 110₁. When drops 216 of the working fluid 214 reach a specific size and coalesce, the energy released from the coalescence causes the working fluid drops 216 to spontaneously jump (shown by lines 236) back to the hydrophilic evaporation surface 204, independent of gravity, providing a return path for an evaporation/condensation cycle, as will be understood by those skilled in the art.

The jumping drops vapor chamber 200 differs from traditional vapor chambers in that traditional vapor chambers rely on capillary action for liquid return, requiring relatively long wicks to allow for the large working fluid flow rates that are necessary for cooling. However, relatively long wicks have a high thermal resistance, which reduces the overall thermal conductivity of the traditional vapor chamber. In jumping drops vapor chambers 200, the capillary limit of traditional vapor chambers is surpassed because the return is achieved by the jumping action previously described. The projections or wicks 224 of the hydrophilic evaporation surface 204 are now only used for capturing the returning working fluid drops 216, and, thus, can be made much shorter and finer than wicks in a traditional vapor chambers. This may lead to much higher thermal conductivities in the jumping drops vapor chamber 200 compared to traditional vapor chambers. Moreover, the finer projections or wicks 224 may allow higher heat flux before boiling incipiency and may expand the range of allowable heat fluxes before dry-out occurs, as will be understood to those skilled in the art. Furthermore, as will also be understood to those skilled in the art, the microelectronic device 110₁ and 110₂ may have specific areas that are hotter than other areas during operation, known as hot spot areas. The jumping drops vapor chamber 200 may act to dynamically mitigate such hot spots areas due to the fact that the evaporation rate of the working fluid 214 will be higher in hot spot areas than other areas, leading to fast temperature uniformity without requiring any special designs for the hot spot areas.

As illustrated in FIG. 4, differing lengths L₁ and L₂ of the jumping drops vapor chamber sidewalls 212 (i.e. the distance between the integrated heat spreader second surface 144 and the back surface 116 of each of the microelectronic devices 110₁ and 110₂) may compensate for the differing heights H₁ and H₂ of the microelectronic devices 110₁ and 110₂ (i.e. the distance between the microelectronic substrate first surface 122 and the back surface 116 of each microelectronic devices 110₁ and 110₂), and, thus, the integrated heat spreader second surface 144 may be substantially planar. Differing lengths L₁ and L₂ of the jumping drops vapor chamber sidewalls 212 may be used since thermal performance of the jumping drops vapor chamber 200 is relatively insensitive to the distance between the evaporation surface 204 and the condensation surface 206 on the scale in which they will be used in microelectronic systems.

In one embodiment of the present description, the jumping drops vapor chamber sidewalls 212 may comprise a seal, such as an O-ring. As will be understood to those skilled in the art, various commercial O-rings or other such materials are available that may be able to withstand temperature and humidity of the proposed environment, including but not limited to perfluoroelastomers (such as DuPont Kalrez®, available from E.I. du Pont de Nemours & Company, Wilmington, Del.) and Parker FF-400® O-rings (available from Parker Hannifin Corporation, Lexington, Ky.). In an embodiment, the jumping drops vapor chamber sidewalls 212 may be compliant to absorb manufacturing tolerances, as will be understood to those skilled in the art. Furthermore, as shown in FIG. 5, grooves 240 can be formed in the back surface 116 of the microelectronic devices 110₁ and 110₂ and/or in the integrated heat spreader second surface 144, if needed, to secure the jumping drops vapor chamber sidewalls 212 in place, e.g. a portion of the jumping drops vapor chamber sidewalls 212 extends into the grooves 240. The grooves 240 may be formed by any known method, including but not limited to surface machining methods such as skiving, dicing, and laser ablation.

As further illustrated in FIG. 5, the integrated heat spreader 200 may include a charging port 250 extending therethrough to the vapor space 202 to provide a means to inject the working fluid 214 and apply a vacuum to the vapor space 202, if needed, once the sidewalls are in place; after which, the charging port 250 may be sealed/blocked. It is also understood that the working fluid 214 could be delivered and a vacuum applied through the sidewall 212.

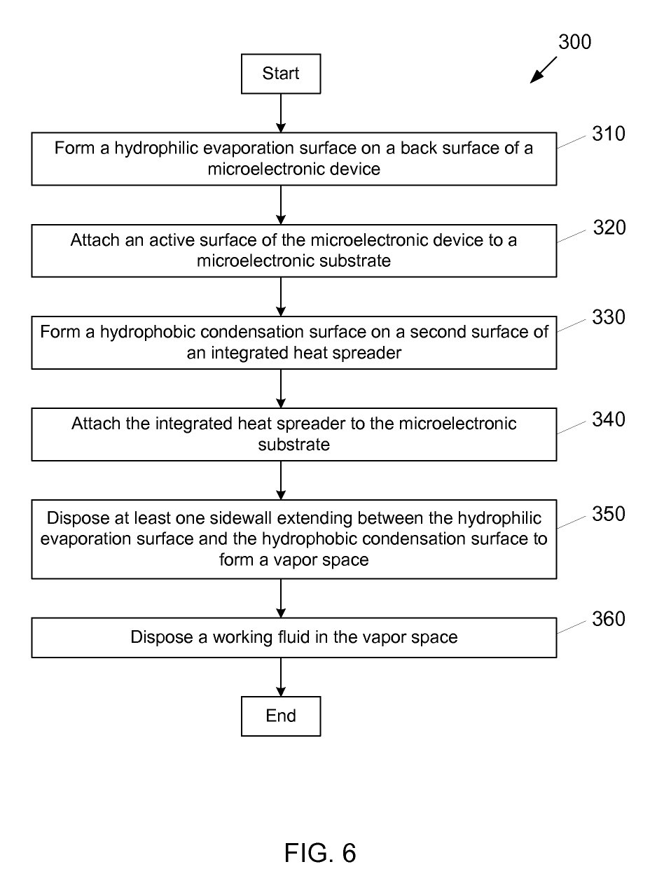

FIG. 6 is a flow chart of a process 300 of fabricating a microelectronic system according to an embodiment of the present description. As set forth in block 310, a hydrophilic evaporation surface may be formed on a back surface of a microelectronic device. An active surface of the microelectronic device may be attached to a microelectronic substrate, as set forth in block 320. As set forth in block 330, a hydrophobic condensation surface may be formed on a second surface of an integrated heat spreader. The integrated heat spreader may be attached to the microelectronic substrate, as set forth in block 340. As set forth in block 350, at least one sidewall may be disposed to extend between the hydrophilic evaporation surface and the hydrophobic condensation surface to form a vapor space. It is understood that the sidewall may be positioned prior to the attachment of the integrated heat spreader. A working fluid may then be disposed in the vapor space, as set forth in block 360. Disposing the working fluid within the vapor space may comprise forming a charging port extending through the integrated heat spreader to the vapor space, injecting the working fluid through the charging port, applying a vacuum, if needed, and then sealing the charging port.

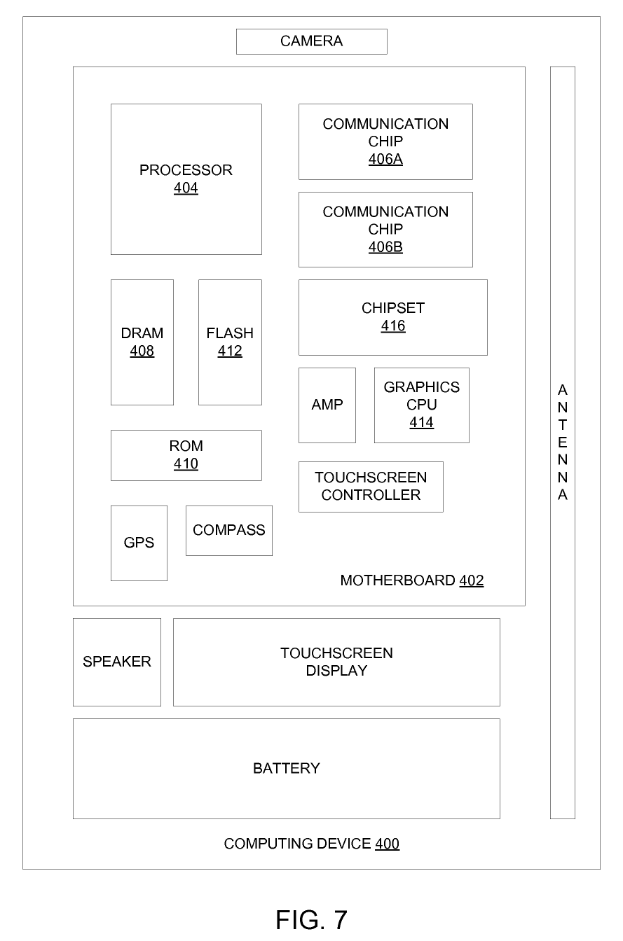

FIG. 7 illustrates an electronic or computing device 400 in accordance with one implementation of the present description. The computing device 400 houses a board 402. The board may include a number of microelectronic components, including but not limited to a processor 404, at least one communication chip 406A, 406B, volatile memory 408 (e.g., DRAM), non-volatile memory 410 (e.g., ROM), flash memory 412, a graphics processor or CPU 414, a digital signal processor (not shown), a crypto processor (not shown), a chipset 416, an antenna, a display, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the microelectronic components may be physically and electrically coupled to the board 402. In some implementations, at least one of the microelectronic components may be a part of the processor 404.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the microelectronic components may include a thermal solution comprising a jumping drops vapor chamber disposed between an integrated heat spreader and a back surface of the microelectronic device within the microelectronic component.

In various implementations, the computing device may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-7. The subject matter may be applied to other microelectronic devices and assembly applications, as well as any appropriate electronic application, as will be understood to those skilled in the art.

The following examples pertain to further embodiments, wherein Example 1 is a microelectronic system, comprising at least one microelectronic device having an active surface and an opposing back surface, wherein the at least one microelectronic device active surface is attached to a microelectronic substrate; an integrated heat spreader, having a first surface and an opposing second surface, attached to the microelectronic substrate; and a jumping drops vapor chamber disposed between the at least one microelectronic device back surface and the integrated heat spreader second surface, wherein the jumping drops vapor chamber comprises a vapor space defined by a hydrophilic evaporation surface formed on the at least one microelectronic device back surface, an opposing hydrophobic condensation surface formed on the integrated heat spreader second surface, and at least one sidewall extending between the hydrophilic evaporation surface and the hydrophobic condensation surface; and a working fluid disposed within the vapor space.

In Example 2, the subject matter of Example 1 can optionally include the hydrophilic evaporation surface comprising a plurality of wicks formed in the at least one microelectronic device back surface.

In Example 3, the subject matter of either Example 1 or 2 can optionally include the hydrophobic condensation surface comprising a hydrophobic material layer formed on the integrated heat spreader second surface.

In Example 4, the subject matter of Example 3 can optionally include the hydrophobic material layer comprises a self-assembled monolayer material selected from the group comprising thiols and silanes.

In Example 5, the subject matter of Example 1 can optionally include the at least one sidewall comprising at least one compliant sidewall.

In Example 6, the subject matter of Example 5 can optionally include the at least one compliant sidewall comprising an O-ring.

In Example 7, the subject matter of any of Examples 1 to 6 can optionally include the working fluid comprising deionized water.

In Example 8, the subject matter of any of Examples 1 to 6 can optionally include the working fluid comprising a dielectric liquid.

In Example 9, the subject matter of any of Examples 1 to 8 can optionally include a charging port extending through the integrated heat spreader to the vapor chamber.

In Example 10, the subject matter of any of Examples 1 to 9 can optionally include a groove formed in at least one of the microelectronic device back surface and the integrated heat spreader second surface; and wherein a portion of the jumping drops vapor chamber sidewall resides within the groove.

In Example 11, the subject matter of any of Examples 1 to 10 can optionally include a second microelectronic device having an active surface and an opposing back surface, wherein the second microelectronic device active surface is attached to the microelectronic substrate; and a second jumping drops vapor chamber disposed between the second microelectronic device back surface and the integrated heat spreader second surface, wherein the second jumping drops vapor chamber comprises a vapor space defined by a hydrophilic evaporation surface formed on the second microelectronic device back surface, an opposing hydrophobic condensation surface formed on the integrated heat spreader second surface, and at least one sidewall extending between the hydrophilic evaporation surface and the hydrophobic condensation surface; and a working fluid disposed within the vapor space.

In Example 12, the subject matter of Example 11 can optionally include a height of the at least one microelectronic device being less than a height of the second microelectronic device; and wherein the jumping drops vapor chamber sidewall is longer than the second jumping drops vapor chamber sidewall.

The following examples pertain to further embodiments, wherein Example 13 is a method for forming a microelectronic system, comprising forming a hydrophilic evaporation surface on a back surface of a microelectronic device; attaching an active surface of the microelectronic device to a microelectronic substrate; forming a hydrophobic condensation surface on a second surface of an integrated heat spreader; attaching the integrated heat spreader to the microelectronic substrate; disposing at least one sidewall extending between the hydrophilic evaporation surface and the hydrophobic condensation surface to form a vapor space; and disposing a working fluid in the vapor space.

In Example 14, the subject matter of Example 13 can optionally include disposing the working fluid within the vapor space comprises forming a charging port extending through the integrated heat spreader to the vapor space, injecting the working fluid through the charging port, and sealing the charging port.

In Example 15, the subject matter of Example 14 can optionally include creating a vacuum within the vapor space through the charging port prior to sealing the charging port.

In Example 16, the subject matter of any of Examples 13 to 15 can optionally include forming the hydrophilic evaporation surface comprising forming a plurality of wicks in the microelectronic device back surface.

In Example 17, the subject matter of any of Examples 13 to 16 can optionally include forming the hydrophobic condensation surface comprising forming a hydrophobic material layer form on the integrated heat spreader second surface.

In Example 18, the subject matter of Example 17 can optionally include forming the hydrophobic condensation surface comprising forming a hydrophobic material layer form on the integrated heat spreader second surface.

In Example 19, the subject matter of any of Examples 13 to 18 can optionally include disposing at least one sidewall extending between the hydrophilic evaporation surface and the hydrophobic condensation surface comprising disposing at least one compliant sidewall extending between the hydrophilic evaporation surface and the hydrophobic condensation surface.

In Example 20, the subject matter of any of Examples 13 to 19 can optionally include disposing the working fluid within the vapor space comprising disposing deionized water within the vapor space.

In Example 21, the subject matter of any of Examples 13 to 19 can optionally include disposing the working fluid within the vapor space comprising disposing a dielectric liquid within the vapor space.

The following examples pertain to further embodiments, wherein Example 22 is an electronic system, comprising a housing; a microelectronic substrate disposed within the housing; at least one microelectronic device having an active surface electrically connected to the microelectronic substrate; an integrated heat spreader, having a first surface and an opposing second surface, attached to the microelectronic substrate; and a jumping drops vapor chamber disposed between the at least one microelectronic device back surface and the integrated heat spreader second surface, wherein the jumping drops vapor chamber comprises: a vapor space defined by a hydrophilic evaporation surface formed on the at least one microelectronic device back surface, an opposing hydrophobic condensation surface formed on the integrated heat spreader second surface, and at least one sidewall extending between the hydrophilic evaporation surface and the hydrophobic condensation surface; and a working fluid disposed within the vapor space.

In Example 23, the subject matter of Example 22 can optionally include the hydrophilic evaporation surface comprising a plurality of wicks formed in the at least one microelectronic device back surface.

In Example 24, the subject matter of either Example 22 or 23 can optionally include the hydrophobic condensation surface comprising a self-assembled monolayer material selected from the group comprising thiols and silanes formed on the integrated heat spreader second surface.

In Example 25, the subject matter of any of Examples 22 to 24 can optionally include the at least one sidewall comprising at least one compliant sidewall.

Having thus described in detail embodiments of the present invention, it is understood that the invention defined by the appended claims is not to be limited by particular details set forth in the above description, as many apparent variations thereof are possible without departing from the spirit or scope thereof.

1. A microelectronic system, comprising:
at least one microelectronic device having an active surface and an opposing back surface, wherein the at least one microelectronic device active surface is attached to a microelectronic substrate;
an integrated heat spreader, having a first surface and an opposing planar second surface, attached to the microelectronic substrate; and
a jumping drops vapor chamber disposed between the at least one microelectronic device back surface and the integrated heat spreader planar second surface, wherein the jumping drops vapor chamber comprises:
a vapor space defined by a hydrophilic evaporation surface formed on the at least one microelectronic device back surface, an opposing hydrophobic condensation surface formed on the integrated heat spreader planar second surface, and at least one sidewall extending between the hydrophilic evaporation surface and the hydrophobic condensation surface, wherein the at least one sidewall contacts the microelectronic device at the microelectronic and contacts the integrated heat spreader at the integrated heat spreader second surface; and
a working fluid disposed within the vapor space.

2. The microelectronic system of claim 1, wherein the hydrophilic evaporation surface comprises a plurality of wicks formed in the at least one microelectronic device back surface.

3. The microelectronic system of claim 1, wherein the hydrophobic condensation surface comprises a hydrophobic material layer formed on the integrated heat spreader planar second surface.

4. The microelectronic system of claim 3, where the hydrophobic material layer comprises a self-assembled monolayer material selected from the group comprising thiols and silanes.

5. The microelectronic system of claim 1, wherein the at least one sidewall comprises at least one compliant sidewall.

6. The microelectronic system of claim 5, wherein the at least one compliant sidewall comprises an O-ring.

7. The microelectronic system of claim 1, wherein the working fluid comprises deionized water.

8. The microelectronic system of claim 1, wherein the working fluid comprises a dielectric liquid.

9. The microelectronic system of claim 1, further including a charging port extending through the integrated heat spreader to the vapor chamber.

10. The microelectronic system of claim 1, further including a groove formed in at least one of the microelectronic device back surface and the integrated heat spreader planar second surface; and wherein a portion of the jumping drops vapor chamber sidewall resides within the groove.

11. The microelectronic system of claim 1, further including a second microelectronic device having an active surface and an opposing back surface, wherein the second microelectronic device active surface is attached to the microelectronic substrate; and
a second jumping drops vapor chamber disposed between the second microelectronic device back surface and the integrated heat spreader planar second surface, wherein the second jumping drops vapor chamber comprises:
a vapor space defined by a hydrophilic evaporation surface formed on the second microelectronic device back surface, an opposing hydrophobic condensation surface formed on the integrated heat spreader planar second surface, and at least one sidewall extending between the hydrophilic evaporation surface and the hydrophobic condensation surface; and
a working fluid disposed within the vapor space.

12. The microelectronic system of claim 11, wherein a height of the at least one microelectronic device is less than a height of the second microelectronic device; and wherein the jumping drops vapor chamber sidewall is longer than the second jumping drops vapor chamber sidewall.

13. A method for forming a microelectronic system, comprising:
forming a hydrophilic evaporation surface on a back surface of a microelectronic device;
attaching an active surface of the microelectronic device to a microelectronic substrate;
forming a hydrophobic condensation surface on a planar second surface of an integrated heat spreader;
attaching the integrated heat spreader to the microelectronic substrate;
disposing at least one sidewall extending between the hydrophilic evaporation surface and the hydrophobic condensation surface to form a vapor space, wherein the at least one sidewall contacts the microelectronic device at the microelectronic and contacts the integrated heat spreader at the integrated heat spreader second surface; and
disposing a working fluid in the vapor space.

14. The method of claim 13, wherein disposing the working fluid within the vapor space comprises forming a charging port extending through the integrated heat spreader to the vapor space, injecting the working fluid through the charging port, and sealing the charging port.

15. The method of claim 14, further including creating a vacuum within the vapor space through the charging port prior to sealing the charging port.

16. The method of claim 13, wherein forming the hydrophilic evaporation surface comprises forming a plurality of wicks in the microelectronic device back surface.

17. The method of claim 13, wherein forming the hydrophobic condensation surface comprises forming a hydrophobic material layer form on the integrated heat spreader planar second surface.

18. The method of claim 17, wherein forming the hydrophobic material layer comprises forming a self-assembled monolayer material selected from the group comprising thiols and silanes.

19. The method of claim 13, wherein disposing at least one sidewall extending between the hydrophilic evaporation surface and the hydrophobic condensation surface comprises disposing at least one compliant sidewall extending between the hydrophilic evaporation surface and the hydrophobic condensation surface.

20. The method of claim 13, wherein disposing the working fluid within the vapor space comprises disposing deionized water within the vapor space

21. The method of claim 13, wherein disposing the working fluid within the vapor space comprises disposing a dielectric liquid within the vapor space

22. An electronic system, comprising:
a housing;
a microelectronic substrate disposed within the housing;
at least one microelectronic device having an active surface electrically connected to the microelectronic substrate and a back surface opposing the active surface;
an integrated heat spreader, having a first surface and an opposing planar second surface, attached to the microelectronic substrate; and
a jumping drops vapor chamber disposed between the at least one microelectronic device back surface and the integrated heat spreader planar second surface, wherein the jumping drops vapor chamber comprises:
a vapor space defined by a hydrophilic evaporation surface formed on the at least one microelectronic device back surface, an opposing hydrophobic condensation surface formed on the integrated heat spreader planar second surface, and at least one sidewall extending between the hydrophilic evaporation surface and the hydrophobic condensation surface, wherein the at least one sidewall contacts the microelectronic device at the microelectronic and contacts the integrated heat spreader at the integrated heat spreader second surface; and
a working fluid disposed within the vapor space.

23. The electronic system of claim 22, wherein the hydrophilic evaporation surface comprises a plurality of wicks formed in the at least one microelectronic device back surface.

24. The electronic system of claim 22, wherein the hydrophobic condensation surface comprises a self-assembled monolayer material selected from the group comprising thiols and silanes formed on the integrated heat spreader planar second surface.

25. The electronic system of claim 22, wherein the at least one sidewall comprises at least one compliant sidewall.
